(19) United States
(12) Patent Application Publication
(10) Pub. No.: US 2015/0179540 A1
(43) Pub. Date: Jun. 25, 2015

(54) SEMICONDUCTOR DEVICE

(71) Applicant: KABUSHIKI KAISHA TOSHIBA, Tokyo (JP)

(72) Inventor: Katsuhiro YASUI, Komatsu Ishikawa (JP)

(21) Appl. No.: 14/326,925

(22) Filed: Jul. 9, 2014

(30) Foreign Application Priority Data
Dec. 19, 2013 (JP) 2013-263093

(51) Int. Cl. H01L 23/36; H01L 23/498

(52) U.S. Cl. CPC H01L 23/36; H01L 23/498; H01L 23/49866

(57) ABSTRACT

A semiconductor device includes a substrate having a first surface and a second surface. A semiconductor chip is disposed on the first surface of the substrate. A first metal pattern is disposed on a central portion of the second surface. A second metal pattern is disposed on the second surface and spaced from the first metal pattern. A thermal conducting material is affixed to the first and second metal patterns. The first metal pattern has no two outer edges that meet to form an angle that is 90° or less, and the second metal pattern is between the first metal pattern and an outer edge of the substrate.

### CROSS-REFERENCE TO RELATED APPLICATION

This application is based upon and claims the benefit of priority from Japanese Patent Application No. 2013-263093, filed Dec. 19, 2013, the entire contents of which are incorporated herein by reference.

### FIELD

Embodiments described herein relate generally to semiconductor devices.

### BACKGROUND

A semiconductor chip may include a discrete semiconductor element that is connected to one side of a circuit substrate. A radiator plate (or heat transfer element) may be connected to the other side of the circuit substrate via solder or the like. The semiconductor chip, the circuit substrate, and the radiator plate are then typically encapsulated by using resin in such a way that at least a part of the radiator plate is exposed in the finished device.

When the semiconductor device thus encapsulated is used, heat is generated from the semiconductor element. The heat is dissipated from the radiator plate, but multiple heating and cooling cycles may cause the device elements to deteriorate, for example, the joint between the solder and the radiator plate may begin to weaken and/or crack. The deterioration of the joint between the solder and the radiator plate also causes deterioration of radiation performance of the semiconductor device. That is, the deterioration of the joint between the solder and the radiator plate may ultimately cause a breakdown of the semiconductor device due to thermal effects.

### DESCRIPTION OF THE DRAWINGS

FIG. 1 depicts the structure of a circuit substrate according to a first embodiment.

FIG. 2 is a plan view of the circuit substrate viewed from a direction A of FIG. 1.

FIG. 3 depicts the cross-section structure of a semiconductor device according to this first embodiment.

FIG. 4 depicts the structure of a circuit substrate according to a comparative example.

FIG. 5 is a plan view of the circuit substrate of the comparative example viewed from a direction B of FIG. 4.

### DETAILED DESCRIPTION

An exemplary embodiment provides a semiconductor device that may suppress deterioration in thermal radiation performance of the semiconductor device.

In an embodiment, a semiconductor device includes a substrate having a first surface and a second surface. A semiconductor chip is disposed on the first surface of the substrate. A first metal pattern is disposed on a central portion of the second surface. A second metal pattern is disposed on the second surface and spaced from the first metal pattern. A thermal conducting material (such as radiator plate) is affixed to the first and second metal patterns. The first metal pattern has no two outer edges that meet to form an angle that is 90° or less, and the second metal pattern is between the first metal pattern and an outer edge of the substrate.

In general, according to another embodiment, a semiconductor device includes a substrate, a semiconductor chip provided on one side of the substrate, a first metal pattern that is provided at a center portion of the other side apposite to the one side and includes a first angular portion, a second metal pattern that includes a second angular portion with an angle smaller than an angle of the first angular portion and is provided on the other side in such a way as to be separated from the first metal pattern, and a thermal conducting material mounted to the first and second metal patterns.

Hereinafter, example embodiments will be described with reference to the drawings. In the following descriptions, common portions between the drawings may be identified with common reference numerals. It should be noted, the specific element dimensional relationships (element size ratios) depicted in each drawing is not intended as a limitation as such depictions are made for purposes of clarity and explanation only and such depictions are not intended to express specific dimensional relationships between elements unless otherwise expressly stated. Thus, disclosed embodiments are not limited to the dimensional ratio(s) illustrated in the drawings.

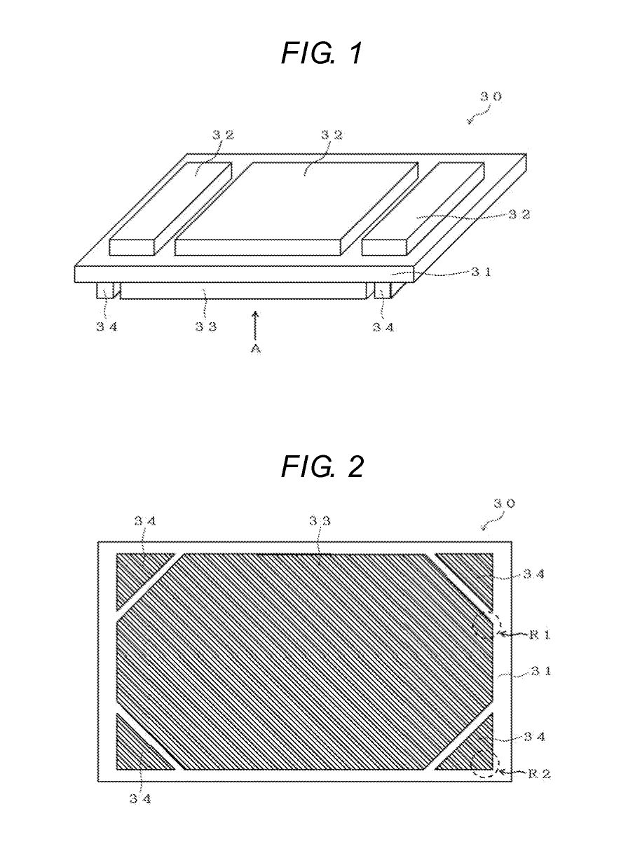

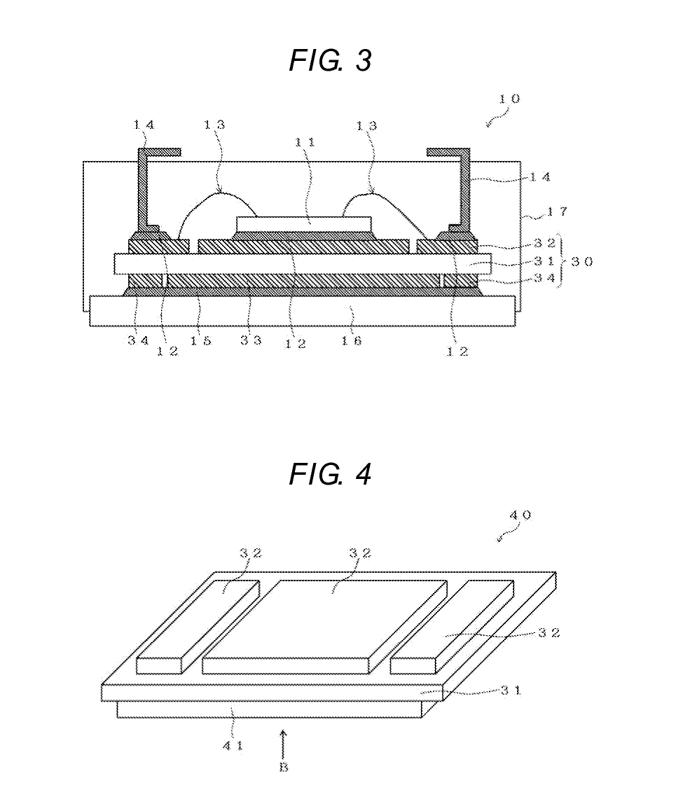

The structure of a semiconductor device 10 will be described with reference to FIGS. 1, 2, and 3. FIG. 1 depicts the structure of a circuit substrate 30 according to this example embodiment, FIG. 2 is a plan view of the circuit substrate 30 viewed from direction A of FIG. 1, and FIG. 3 depicts the cross-section structure of the semiconductor device 10.

The circuit substrate 30 includes a ceramic substrate 31, a surface metal pattern (electrode metal pattern) 32, a first metal pattern 33, and a second metal pattern 34. The ceramic substrate 31 has a planar (plate-like) shape and has a first side (a front side) and a second side (a back side) opposite to the first side. The ceramic substrate 31 may have, for example, a rectangular planar shape. Moreover, although the ceramic substrate 31 in this example is formed of alumina, the material of the substrate 31 is not limited to a particular material and any suitable material may be used.

On a front side (first surface) of the ceramic substrate 31, the surface metal pattern 32 is provided.

The surface metal pattern 32 may be divided into a first portion (central portion of pattern 32 depicted in FIG. 1) to which a semiconductor chip 11 is to be connected and a second portion (e.g., left/right side portion of pattern 32 depicted in FIG. 1) to which an external connection electrode 14 (see FIG. 3) is to be connected.

Incidentally, in FIG. 1, the first portion of the surface metal pattern 32 is provided as single, unitary portion and the second portion is provided as two divided (e.g., left and right side portions) but this is merely an example, and the first portion may be provided as a plurality of sub-portions and likewise the second portion may be provided as a single, unitary portion or as a plurality (two or more) of sub-portions.

Moreover, inclusion of a second portion of the surface metal pattern is not necessarily required and the second portion may be omitted in some embodiments.

On a back side (second surface) of the ceramic substrate 31, the first metal pattern 33 and the second metal pattern 34 are provided. In this example, as illustrated in FIG. 2, the first metal pattern 33 is provided at the central portion of the back side of the ceramic substrate 31, and the second metal pattern 34 is provided in an “angular portion” on the back side of the ceramic substrate 31. That is, the second metal pattern 34 is provided between an edge and/or corner of the ceramic substrate 31 and the first metal pattern 33, which located on a central portion of the back side of the ceramic substrate 31. The first metal pattern 33 and the second metal pattern 34 are provided in such a way as to leave a space between the first metal pattern 33 and the second metal pattern 34.

The semiconductor device 10 includes the semiconductor chip 11, mounting solder 12, bonding wires 13, the external connection electrodes 14, back-side solder 15, a radiator plate (a thermal conducting material) 16, resin 17, and the circuit substrate 30.

The semiconductor chip 11 may be a vertical power semiconductor element formed of a metal oxide semiconductor field-effect transistor (MOSFET), for example.

On one side of the semiconductor chip 11, a source electrode (not specifically illustrated in the drawing) is exposed, and, on the other side, a drain electrode is exposed (not specifically illustrated in the drawing). The source/drain electrodes may be on either side of the semiconductor chip 11.

Moreover, on a front side (upper surface) of the semiconductor chip 11, an electrode contact connected to a gate electrode is also exposed (though not specifically illustrated in the drawing).

In addition to a MOSFET, the semiconductor chip 11 may also, or instead, include, for example, an insulated gate bipolar transistor (IGBT) or a diode.

On the surface metal pattern 32 provided on the front side of the ceramic substrate 31, the semiconductor chip 11 is fixed (mounted) with the mounting solder 12 being sandwiched between the surface metal pattern 32 and the semiconductor chip 11. For example, a drain electrode exposed on the lower surface of the semiconductor chip 11 is connected to the surface metal pattern 32 by soldering using the mounting solder 12. A source electrode and the electrode contact which are exposed on the upper surface of the semiconductor chip 11 are electrically connected, via the bonding wires 13, to the surface metal pattern 32 to which the semiconductor chip 11 is not soldered. That is, the source electrode and the electrode contact are respectively connected to, for example, the second portion of the surface metal pattern 32. Thus, the electrode contact may be connected, as an example, to left side portion of the surface metal pattern 32 and the source electrode may be connected to the right side portion of the surface metal pattern. Those skilled in the art will recognize that the connections between semiconductor chip 11 and the surface metal pattern 32 may be made in many ways and in many configurations depending on the specific requirements of the semiconductor chip 11 being mounted on circuit substrate 30 and/or the intended end use of semiconductor device 10. Similarly, the surface metal pattern 32 can be varied as necessary to accommodate the connections necessary for providing external electrical connections for semiconductor chip 11.

Moreover, on the surface metal pattern 32 to which the semiconductor chip 11 is not connected, the external connection electrodes 14 are fixed with the mounting solder 12 being sandwiched between the surface metal pattern 32 and the external connection electrodes 14. The external connection electrodes 14 each have a copper plate which has a rectangular shape, for example. As described earlier, since the surface metal pattern 32 is electrically connected to the source electrode and the gate electrode of the semiconductor chip 11, an external connection electrode 14 which is at the same potential as the source electrode and an external connection electrode 14 which is at the same potential as the gate electrode are provided in this embodiment.

The first metal pattern 33 and the second metal pattern 34, which are provided on the back side (second surface) of the ceramic substrate 31 are connected to the radiator plate 16 with the solder 15 being sandwiched between the first metal pattern 33 and the radiator plate 16 and the second metal pattern 34 and the radiator plate 16.

The semiconductor chip 11, the mounting solder 12, the bonding wires 13, the external connection electrodes 14, the solder 15, and the radiator plate 16 are encapsulated with the resin 17 in such a way that a side (bottom surface) of the radiator plate 16, that is, the side to which the solder 15 is not connected is exposed (not covered by resin 17). Additional, a part of each external connection electrode 14 is exposed (not covered by the resin 17).

Incidentally, the external connection electrodes 14, the surface metal pattern 32, the first metal pattern 33, and the second metal pattern 34 are formed of copper in this example. Moreover, the bonding wires 13 in this example are formed of aluminum, and the radiator plate 16 is formed of an alloy in this example. However, these materials are merely possible materials, and implementation is also possible using other metals and conductive materials.

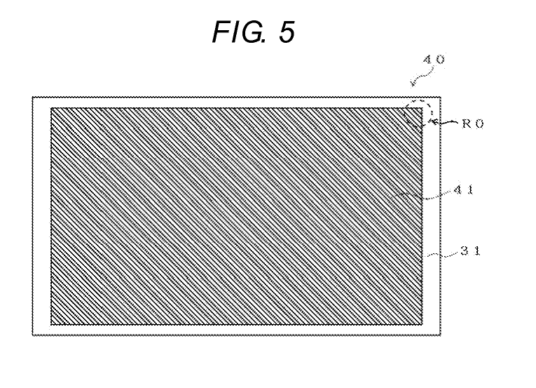

The advantages of the semiconductor device 10 according to this embodiment will be described with reference to a comparative example. FIG. 4 depicts the structure of a circuit substrate 40 according to the comparative example, and FIG. 5 is a plan view of the circuit substrate 40 viewed from direction B of FIG. 4.

The circuit substrate 40 differs from the circuit substrate 30 in that the metal pattern provided on the back side of the ceramic substrate 31 is not divided into a plurality of portions. That is, the circuit substrate 40 does not have the first metal pattern 33 and the second metal pattern 34. Furthermore, as illustrated in FIG. 5, the circuit substrate 40 has solder 41 provided almost completely over the back side of the ceramic substrate 31 (covering the metal pattern provided thereon). The solder 41 is sandwiched between the metal pattern on the backside of the ceramic substrate 31 and the radiator plate 16. The other structure of the comparative example is similar to that of the circuit substrate 30.

A problem will arise when the circuit substrate 40 is used in a semiconductor device having a structure similar to that of the semiconductor device 10. When the comparative semiconductor device having the circuit substrate 40 is put in an environment in which heating and cooling are alternately performed (for example, periodic switching between the ON state and the OFF state of the semiconductor chip 11), stress caused by a difference in coefficient of thermal expansion between the radiator plate 16 and the ceramic substrate 31 is applied to the solder 41. This stress may eventually form a crack in the solder 41.

In particular, since the stress is concentrated on an angular (corner) portion (R0) of the solder 41 whose angle is approximately 90°, as depicted in FIG. 5, the crack in solder 41 will tend to occur at the corner portion(s) of solder 41.

The crack that occurs at a corner portion of the solder 41 may eventually spread to the whole joint formed by solder 41 between ceramic substrate 31 and the radiator plate 16, thus weakening the mechanical and thermal connection between the ceramic substrate 31 and the radiator plate 16. When the joint between the ceramic substrate 31 and the radiator plate 16 is weakened, the thermal conductance between ceramic substrate 31 and the radiator plate 16 is reduced and thermal radiation performance of the packaged device is reduced. As a result, the temperature rises rapidly in the semiconductor device of the comparative example, which may result in device breakdown.

In the semiconductor device 10, the ceramic substrate 31 has a backside metal pattern including the first metal pattern 33 and the second metal pattern 34. The first metal pattern 33 and the second metal pattern 34 are spaced from each other. The first metal pattern 33 has an angular portion (a first angular portion R1) whose angle is greater than 90° (an obtuse angle). That is, as depicted, the first metal pattern 34 does not have what might be referred to as “sharp” corner portions (i.e., 90° or acute corners). The corner portions of the first metal pattern 34 will not concentrate stress as much as 90° or acute corners. The second metal pattern 34 has an angular (corner) portion (a second angular portion R2) whose angle is 90° or an acute angle. Therefore, when heating and cooling are alternately performed on the semiconductor device 10, the stress that is generated between the ceramic substrate 31 and the radiator plate 16 tends to become concentrated on the second angular portion R2 of the second metal pattern 34. On the other hand, since the first angular portion R1 of the first metal pattern 33 has an obtuse angle, concentration of stress is less on the first metal pattern as compared to the second metal pattern 34.

As in the case with the solder 41 provided on the circuit substrate 40 according to the comparative example, a crack caused by thermal stress tends to occur in the second angular portion R2 of the second metal pattern 34 rather than the first angular portion R1. However, since the first metal pattern 33 and the second metal pattern 34 are spaced from each other, a crack that spreads from the second angular portion R2 in the second metal pattern 34 will be limited to the second metal pattern 34 and will not easily propagate through the entire solder 15 joint between the ceramic substrate 31 and the radiator plate 16. That is, although the joint between the second metal pattern 34 and the ceramic substrate 31 may be weakened by the crack caused by thermal stress, the joint between the first metal pattern 33 and the ceramic substrate 31 is not necessarily similarly weakened. Since the first metal pattern 33 provided at the central portion of the back side of the ceramic substrate 31 generally may have a larger area the than the second metal pattern 34, it becomes possible to maintain sufficient radiation performance for the semiconductor device 10 even after an initial crack forms in the device. As a result, the semiconductor device 10 may maintain the radiation performance of heat that is generated from the semiconductor chip 11, which makes it possible to prevent a breakdown of the semiconductor device 10.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate having a first surface and a second surface opposite the first surface;
a semiconductor chip disposed on the first surface;
a first metal pattern disposed on a central portion of the second surface;
a second metal pattern disposed on the second surface and spaced from the first metal pattern; and
a thermal conducting material affixed to the first and second metal patterns, wherein
the first metal pattern has no two outer edges that meet to form an angle that is 90° or less, and
the second metal pattern is between the first metal pattern and an outer edge of the substrate.

2. The semiconductor device of claim 1, wherein at least two edges of the second metal pattern meet to form an angle that is 90° or less.

3. The semiconductor device of claim 1, wherein the substrate is rectangular.

4. The semiconductor device of claim 3, wherein the second metal pattern is between the first metal pattern and a corner portion of the substrate.

5. The semiconductor device of claim 4, wherein the second metal pattern is in the shape of a right triangle.

6. The semiconductor device of claim 5, wherein the first metal pattern is in the shape of an octagon.

7. The semiconductor device of claim 3, wherein the second metal pattern is between the first metal pattern and each corner portion of the substrate.

8. The semiconductor device of claim 7, wherein the first metal pattern in the shape of an octagon.

9. The semiconductor device of claim 3, wherein the first metal pattern in the shape of an octagon.

10. The semiconductor device of claim 1, wherein the substrate includes ceramic material.

11. The semiconductor device of claim 1, wherein a total area of first metal pattern, when viewed from a direction orthogonal to the second surface, is greater than a total area of the second metal pattern, when viewed from the direction orthogonal to second surface.

12. A semiconductor device, comprising:
a ceramic substrate having a first surface and a second surface opposite the first surface and being a rectangular shape;
an electrode metal pattern disposed on the first surface;
a semiconductor chip connected to electrode metal pattern;
a first metal pattern disposed on a central portion of the second surface;
a second metal pattern disposed on the second surface and spaced from the first metal pattern; and
a radiator plate mounted on the first and second metal patterns, wherein
the first metal pattern has no two outer edges that meet to form an angle that is 90° or less, and
the second metal pattern is between the first metal pattern and each corner of the ceramic substrate.

13. The semiconductor device of claim 12, wherein the second metal pattern comprises a right triangle shaped portion disposed in each corner of the ceramic substrate.

14. The semiconductor device of claim 13, wherein the first metal pattern has an octagon shape.

15. The circuit substrate of claim 14, wherein a total area of first metal pattern, when viewed from a direction orthogonal to the second surface, is greater than a total area of the second metal pattern, when viewed from the direction orthogonal to second surface.

16. A semiconductor device, comprising:
a substrate having a first surface and a second surface opposite the first surface;
an electrode metal pattern disposed on the first surface;
a semiconductor chip connected to the electrode metal pattern;
a first metal pattern disposed on a central portion of the second surface;
a second metal pattern disposed on the second surface and spaced from the first metal pattern;
a radiator plate affixed to the first and second metal patterns; and
a resin material that encapsulates the semiconductor chip and the substrate while leaving a surface of the radiator plate exposed, wherein
the first metal pattern has no two outer edges that meet to form an angle that is 90° or less, and
the second metal pattern is between the first metal pattern and an outer edge of the substrate.

17. The semiconductor device of claim 16, wherein the substrate is ceramic material and rectangular.

18. The semiconductor device of claim 16, wherein the second metal pattern is disposed between the first metal pattern and each corner of the substrate.

19. The semiconductor device of claim 16, wherein a total area of first metal pattern, when viewed from a direction orthogonal to the second surface, is greater than a total area of the second metal pattern, when viewed from the direction orthogonal to second surface.

20. The semiconductor device of claim 16, wherein the substrate comprises alumina, and the first and second metal patterns comprise copper.
